(19) United States
(12) Patent Application Publication
(10) Pub. No.: US 2010/0092009 A1
(43) Pub. Date: Apr. 15, 2010

(54) AUDIO OUTPUT DEVICE

(76) Inventor: Kazuhiro SHIMOMURA, Osaka (JP)

Correspondence Address: MCDERMOTT WILL & EMERY LLP, 600 13TH STREET, NW, WASHINGTON, DC, 20005-3096, US

(21) Appl. No.: 12/477,465

(22) Filed: Jun. 3, 2009

(30) Foreign Application Priority Data
Oct. 9, 2008 (JP) 2008-262802

(51) Int. Cl. H03F 99/00

(52) U.S. Cl. 381/120

(57) ABSTRACT

An amplification circuit amplifies an input signal. A signal detecting circuit detects whether the input signal is in a signal present state or in a signal absent state. A period detecting circuit detects a signal present duration for which the signal detecting circuit detects that the input signal is in the signal present state. A time setting circuit sets a control waiting time, depending on the signal present duration detected by the period detecting circuit. A control circuit limits outputting of the amplification circuit after the control waiting time set by the time setting circuit has elapsed since the signal detecting circuit detected the signal absent state of the input signal.

### CROSS REFERENCE TO RELATED APPLICATIONS

This application claims priority under 35 U.S.C. § 119(a) on Patent Application No. 2008-262802 filed in Japan on Oct. 9, 2008, the entire contents of which are hereby incorporated by reference.

### BACKGROUND

The present disclosure relates to an audio output device for amplifying and outputting an input signal, and more particularly, to a technology of reducing noise of an audio output device including a loudspeaker or the like.

In recent years, a technique of reducing noise of an audio output device in the absence of a signal has been proposed (see, for example, International Publication WO 2006/087870). FIG. 4 shows a configuration of a conventional audio output device. In this audio output device, an amplification circuit 91 amplifies an input signal Vin using a Bridged TransLess (BTL) design to generate output signals Vo1 and Vo2. The amplification circuit 91 includes a noninverting amplifier 901 for amplifying the input signal Vin, and an inverting amplifier 902 for inverting and amplifying the input signal Vin. A loudspeaker 92 is driven by the output signals Vo1 and Vo2. A signal detecting circuit 93 compares a signal level of the input signal Vin with a predetermined level. When detecting that the input signal Vin is in a signal present state (the signal level of the input signal Vin is higher than the predetermined level), the signal detecting circuit 93 sets a detection signal S93 to be at a high level. When detecting that the input signal Vin is in a signal absent state (the signal level of the input signal Vin is lower than the predetermined level), the signal detecting circuit 93 sets the detection signal S93 to be at a low level. A delay circuit 94 adds a delay time ΔT90 to the detection signal S93 and outputs the resultant signal as a delay signal S94 only when the detection signal S93 transitions from the high level to the low level (i.e., the input signal Vin transitions from the signal present state to the signal absent state). The control circuit 95 drives the amplification circuit 91 for a period of time that the delay signal S94 is at a high level, and stops the amplification circuit 91 for a period of time that the delay signal S94 is at a low level.

Next, an operation of the audio output device of FIG. 4 will be described with reference to FIG. 5.

At time t0, when the input signal Vin transitions from the signal absent state to the signal present state, the detection signal S93 transitions from the low level to the high level. In response to the transition of the detection signal S93, the delay circuit 94 causes the delay signal S94 to transition from the low level to the high level. As a result, the amplification circuit 91 amplifies the input signal Vin to generate the output signals Vo1 and Vo2.

At time t1, when the input signal Vin becomes substantially equal to a noise level (i.e., when the input signal Vin transitions from the signal present state to the signal absent state), the detection signal S93 transitions from the high level to the low level. After the delay time ΔT90 has elapsed since the transition of the detection signal S93 (i.e., at time t2), the delay circuit 94 causes the delay signal S94 to transition from the high level to the low level. As a result, the amplification circuit 91 stops generating the output signals Vo1 and Vo2 at time t2.

Here, if the detection signal S93 transitions from the low level to the high level during a period of time from when the detection signal S93 transitions from the high level to the low level until the delay time ΔT90 elapses, the delay circuit 94 does not cause the delay signal S94 to transition from the high level to the low level. In other words, if a period of time for which the input signal Vin continues to be in the signal absent state (signal absent duration) is shorter than the delay time ΔT90, the delay signal S94 is maintained at the high level, and the amplification circuit 91 continues to be driven. On the other hand, if the signal absent duration is longer than the delay time ΔT90, the delay signal S94 transitions from the high level to the low level, and the amplification circuit 91 is stopped. Thus, by controlling the driving/stopping of the amplification circuit 91, depending on the signal absent duration, input noise and noise occurring in the amplification circuit 91 are blocked, thereby reducing noise output from the loudspeaker 92.

However, when an input signal, such as a music signal which fades out at an end portion of a song (its signal level is gradually decreased), is processed, this fade-out period may include a period of time (small-amplitude period) for which the signal level of the input signal fluctuates in the vicinity of the predetermined level set in the signal detecting circuit 93. In this case, if the delay time ΔT90 of the delay circuit 94 is shorter than the small-amplitude period, the amplification circuit 91 alternately repeats driving/stopping, so that interruptions occur in sound output from the loudspeaker 92, resulting in unnatural sound. To avoid such unnatural sound, it is necessary to cause the delay time ΔT90 of the delay circuit 94 to be longer than the small-amplitude period.

Also, when an input signal, such as a short-sound signal which indicates a key touch sound of an information communication apparatus (e.g., a mobile telephone, etc.), is processed, a period of time for which the signal present state continues is considerably short. Therefore, if the delay time ΔT90 of the delay circuit 94 is excessively long, since the amplification circuit 91 is driven until the end of the delay time ΔT90, noise which occurs after the end of the input signal is emphasized, resulting in unpleasant sound. To avoid such unpleasant sound, it is necessary to decrease the delay time ΔT90 of the delay circuit 94 so that noise is not heard or recognized.

As described above, when the delay time ΔT90 of the delay circuit 94 is excessively short, interruptions occur in output sound. When the delay time ΔT90 of the delay circuit 94 is excessively long, noise is emphasized. Therefore, it is difficult to appropriately set the delay time ΔT90 of the delay circuit 94.

### SUMMARY

Therefore, an object of the present disclosure is to provide an audio output device which can prevent signal interruptions and reduce noise which occurs after the end of an input signal.

According to one aspect of the present disclosure, an audio output device includes an amplification circuit configured to amplify an input signal, a signal detecting circuit configured to detect whether the input signal is in a signal present state or in a signal absent state, a period detecting circuit configured to detect a signal present duration for which the signal detecting circuit detects that the input signal is in the signal present state, a time setting circuit configured to set a control waiting time, depending on the signal present duration detected by the period detecting circuit, and a control circuit configured to limit outputting of the amplification circuit after the control waiting time set by the time setting circuit has elapsed since the signal detecting circuit detected the signal absent state of the input signal. The audio output device adjusts the control waiting time, depending on the signal present duration, thereby making it possible to prevent an output signal (amplified input signal) from being interrupted and reduce noise which occurs after the end of an input signal.

### BRIEF DESCRIPTION OF THE DRAWINGS

FIG. 1 is a diagram showing an example configuration of an audio output device.

FIG. 2 is a timing chart for describing an operation of the audio output device of FIG. 1 when a signal present duration is longer than a predetermined period of time.

FIG. 3 is a timing chart for describing an operation of the audio output device of FIG. 1 when the signal present duration is shorter than the predetermined period of time.

FIG. 4 is a diagram showing a configuration of a conventional audio output device.

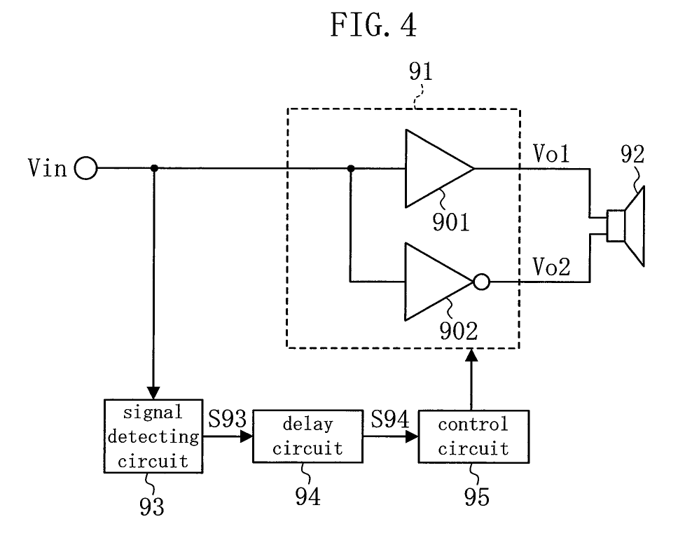

FIG. 5 is a timing chart for describing an operation of the conventional audio output device.

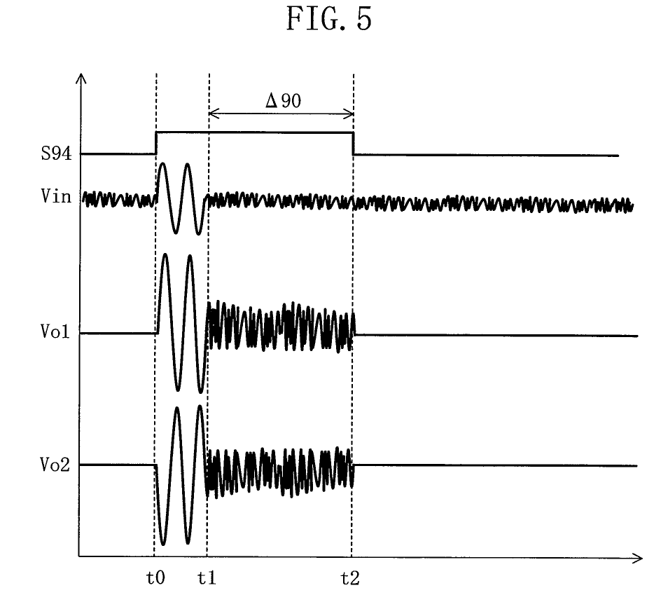

### DETAILED DESCRIPTION

Hereinafter, embodiments of the present disclosure will be described in detail with reference to the accompanying drawings.

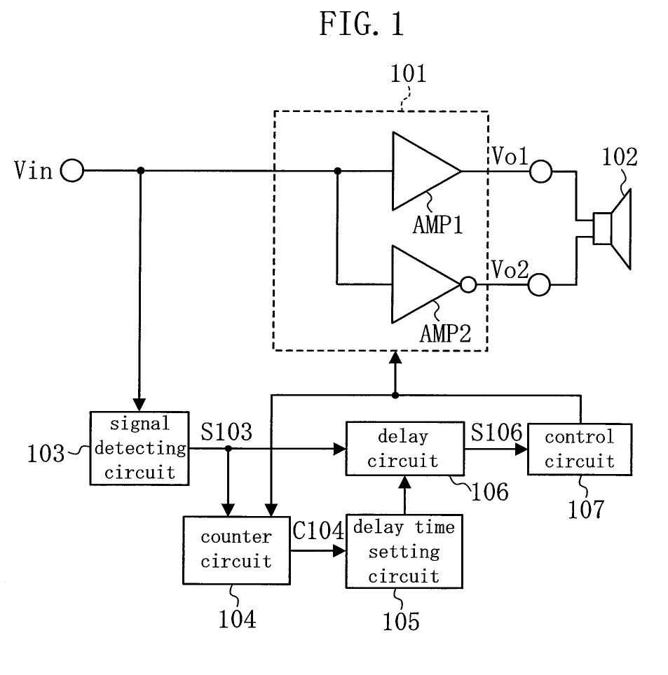

FIG. 1 shows an example configuration of the audio output device. The device includes an amplification circuit 101, a loudspeaker 102, a signal detecting circuit 103, a counter circuit 104, a delay time setting circuit 105, a delay circuit 106, and a control circuit 107.

The amplification circuit 101 amplifies an input signal Vin using a Balanced TransformerLess (BTL) design to generate output signals Vo1 and Vo2. The amplification circuit 101 includes a noninverting amplifier AMP1 for amplifying the input signal Vin to generate the output signal Vo1, and an inverting amplifier AMP2 for inverting and amplifying the input signal Vin to generate the output signal Vo2. The loudspeaker 102 is driven by the output signals Vo1 and Vo2.

The signal detecting circuit 103 compares a signal level of the input signal Vin with a predetermined level. When detecting that the input signal Vin is in a signal present state (the signal level of the input signal Vin is higher than the predetermined level), the signal detecting circuit 103 sets a detection signal S103 to be at a high level. When detecting that the input signal Vin is in a signal absent state (the signal level of the input signal Vin is lower than the predetermined level), the signal detecting circuit 103 sets the detection signal S103 to be at a low level.

The counter circuit 104 (period detecting circuit) starts counting when the detection signal S103 transitions to the high level, and stops counting when the detection signal S103 transitions to the low level. In other words, the counter circuit 104 measures, by counting, a period of time for which the detection signal S103 is at the high level (the input signal Vin continues to be in the signal present state: signal present duration). The counter circuit 104 also resets a count value C104 in response to a control of the control circuit 107.

The delay time setting circuit 105 (time setting circuit) sets a delay time (control waiting time) of the delay circuit 106, depending on the count value C104 of the counter circuit 104. The delay time setting circuit 105 sets the delay time of the delay circuit 106 to a period of time ΔT2 until the count value C104 exceeds a predetermined value, and changes the delay time of the delay circuit 106 from the time period ΔT2 to a period of time ΔT3 which is longer than the time period ΔT2 when the count value C104 exceeds the predetermined value. The delay time setting circuit 105 also sets the delay time of the delay circuit 106 to the time period ΔT2 when the count value C104 is reset.

The delay circuit 106 adds the delay time set by the delay time setting circuit 105 to the transition from the high level to the low level of the detection signal S103. Specifically, when the detection signal S103 transitions from the low level to the high level, the delay circuit 106 causes a delay signal S106 to transition from a low level to a high level. When the detection signal S103 transitions from the high level to the low level, the delay circuit 106 causes the delay signal S106 to transition from the high level to the low level after the delay time set by the delay time setting circuit 105 elapses. Here, if the detection signal S103 transitions from the low level to the high level during a period of time from when the detection signal S103 transitions from the high level to the low level until the delay time set by the delay time setting circuit 105 elapses, the delay circuit 106 maintains the delay signal S106 at the high level. Thus, if a period of time for which the detection signal S103 is at the low level (the input signal Vin continues to be in the signal absent state: signal absent duration) is shorter than the delay time, the delay circuit 106 maintains the delay signal S106 at the high level. If the signal absent duration is longer than the delay time, the delay circuit 106 causes the signal level of the delay signal S106 to transition from the high level to the low level.

The control circuit 107 drives the amplification circuit 101 for a period of time that the delay signal S106 is at the high level, and stops the amplification circuit 101 for a period of time that the delay signal S106 is at the low level. The control circuit 107 also causes the counter circuit 104 to reset the count value C104 when the delay signal S106 transitions from the high level to the low level. As a result, the counter circuit 104 can measure, by counting, the signal present duration included in a period of time that the amplification circuit 101 is being driven.

(Operation)

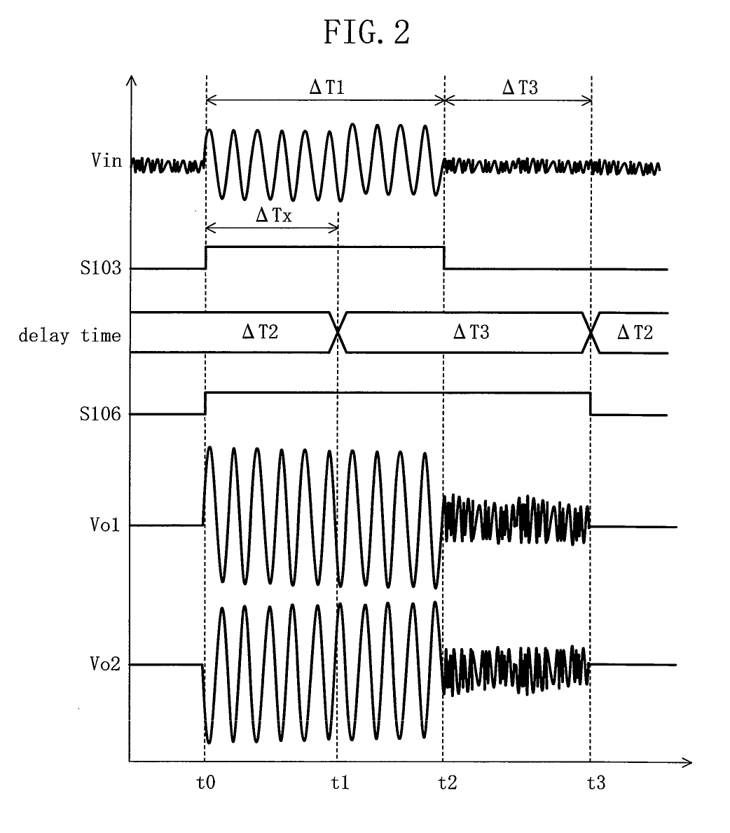

Next, an operation of the audio output device of FIG. 1 where a signal present duration ΔT1 is longer than a predetermined period of time ΔTx, will be described with reference to FIG. 2. Note that the count value C104 of the counter circuit 104 is assumed to exceed the predetermined value when the signal present duration exceeds the predetermined time period ΔTx.

At time t0, the input signal Vin transitions from the signal absent state to the signal present state, and the detection signal S103 transitions from the low level to the high level. As a result, the counter circuit 104 starts measuring the signal present duration by counting. On the other hand, the delay circuit 106 causes the delay signal S106 to transition from the low level to the high level in response to the transition of the detection signal S103. The amplification circuit 101 amplifies the input signal Vin to generate the output signals Vo1 and Vo2.

At time t1 which is the predetermined time period ΔTx after time t0, the count value C104 of the counter circuit 104 exceeds the predetermined value, and the delay time setting circuit 105 extends the delay time of the delay circuit 106 from the time period ΔT2 to the time period ΔT3.

At time t2, the input signal Vin becomes substantially equal to a noise level (i.e., the input signal Vin transitions from the signal present state to the signal absent state), and the detection signal S103 transitions from the high level to the low level. Since the delay time of the delay circuit 106 has been extended to the time period ΔT3, the delay circuit 106 causes the delay signal S106 to transition from the high level to the low level after the time period ΔT3 has elapsed since the transition from the high level to the low level of the detection signal S103 (i.e., at time t3).

At time t3, the delay signal S106 transitions from the high level to the low level, and the amplification circuit 101 stops generating the output signals Vo1 and Vo2. The counter circuit 104 resets the count value C104, and the delay time setting circuit 105 changes the delay time of the delay circuit 106 from the time period ΔT3 back to the time period ΔT2.

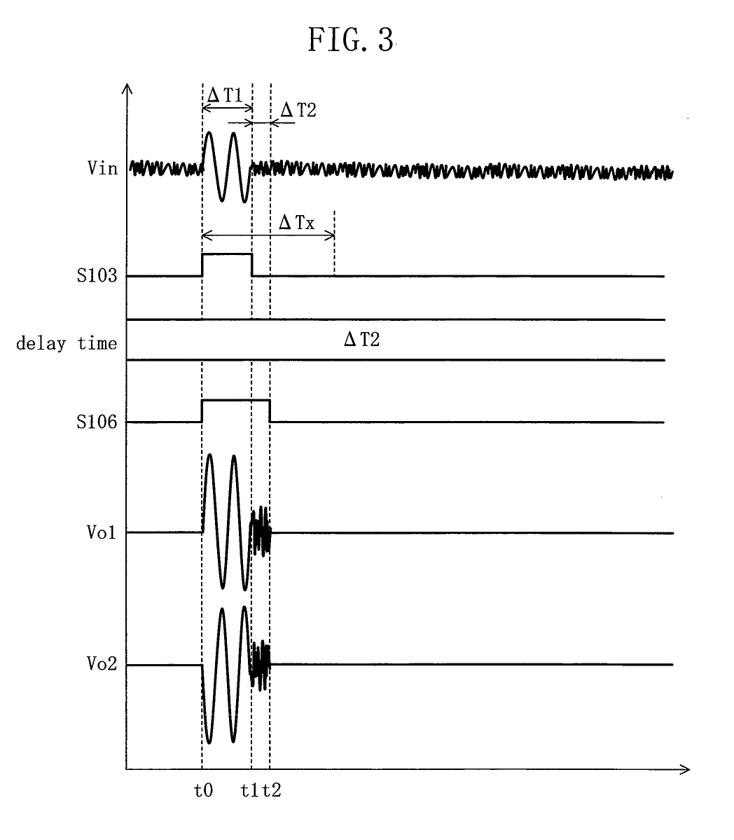

Next, an operation of the audio output device of FIG. 1 where the signal present duration ΔT1 is shorter than the predetermined time period ΔTx, will be described with reference to FIG. 3.

At time t0, the input signal Vin transitions from the signal absent state to the signal present state, and the detection signal S103 and the delay signal S106 transition from the low level to the high level. The counter circuit 104 starts measuring the signal present duration by counting.

At time t1, the input signal Vin transitions from the signal present state to the signal absent state. In this case, since the count value C104 of the counter circuit 104 does not exceed the predetermined value, the delay time setting circuit 105 maintains the delay time (ΔT2) of the delay circuit 106. Therefore, the delay circuit 106 causes the delay signal S106 to transition from the high level to the low level after the time period ΔT2 has elapsed since the transition from the high level to the low level of the detection signal S103 (i.e., at time t2).

At time t2, the delay signal S106 transitions from the high level to the low level, and the amplification circuit 101 stops generating the output signals Vo1 and Vo2.

Thus, when the signal present duration ΔT1 is longer than the predetermined time period ΔTx, the delay time of the delay circuit 106 is extended from the time period ΔT2 to the time period ΔT3. When the signal present duration ΔT1 is shorter than the predetermined time period ΔTx, the delay time (ΔT2) of the delay circuit 106 is maintained.

For example, it is assumed that an audio signal, such as a music signal which fades out at an end portion of a song (its signal level is gradually decreased), is input as the input signal Vin to the audio output device of FIG. 1. In this case, during a portion of this fade-out period in which the signal level of the input signal Vin fluctuates in the vicinity of a predetermined level (small-amplitude period), even if valid audio information is present, the input signal Vin is determined as being in the “signal absent state,” so that the detection signal S103 transitions to the low level. The length of the small-amplitude period varies among songs and is typically shorter than about one second. The length of a song is typically longer than two seconds. Thus, such an audio signal continues to be in the signal present state for two seconds or more, followed by the small-amplitude period of about one second.

As another example, it is assumed that an audio signal, such as a short-sound signal indicating a key touch sound of an information communication apparatus (e.g., a mobile telephone, etc.), is input as the input signal Vin to the audio output device of FIG. 1. In this case, a period of time for which the detection signal S103 is at the high level after the input signal Vin is determined as being in the “signal present state”, is considerably short. A period of time for which the signal level of the short-sound signal is higher than a predetermined level is typically shorter than two seconds. In other words, such an audio signal has a signal present duration of shorter than two seconds, and does not contain valid audio information after the signal present duration elapses.

Therefore, the time period ΔT2 is set to “0.1 seconds” (a period of time for which noise is not heard or recognized), and the time period ΔT3 is set to “about one second” (a period of time substantially equal to the small-amplitude period). In addition, the delay time setting circuit 105 is set so as to change the delay time of the delay circuit 106 from the time period ΔT2 to the time period ΔT3 when the signal present duration exceeds “two seconds.” As a result, it is possible to prevent the output sound of the loudspeaker 102 from being interrupted during the fade-out period of a music signal. In addition, it is possible to prevent the occurrence of unpleasant noise after the end of a short-sound signal.

As described above, a period of time (control waiting time) from when the input signal Vin transitions from the signal present state to the signal absent state until the amplification circuit 101 is stopped, is adjusted, depending on the signal present duration. As a result, it is possible to prevent the output signals Vo1 and Vo2 from being interrupted. In addition, it is possible to reduce noise which occurs after the end of an input signal (after the end of supply of a valid input signal).

Although it has been assumed above that the delay time setting circuit 105 sets the delay time of the delay circuit 106 to one of the time periods ΔT2 and ΔT3, the delay time setting circuit 105 may set the delay time of the delay circuit 106 to one of three or more delay times, depending on the signal present duration.

The aforementioned audio output device adjusts the control waiting time, depending on the signal present duration, thereby making it possible to prevent a signal from being interrupted and reduce noise which occurs after the end of an input signal. Therefore, the audio output device is useful for, for example, a system including an information communication apparatus equipped with a loudspeaker or the like.

The present disclosure is not limited to the embodiments above. Various changes and modifications can be made without departing the spirit and scope of the present disclosure.

What is claimed is:

1. An audio output device comprising:
an amplification circuit configured to amplify an input signal;
a signal detecting circuit configured to detect whether the input signal is in a signal present state or in a signal absent state;
a period detecting circuit configured to detect a signal present duration for which the signal detecting circuit detects that the input signal is in the signal present state;
a time setting circuit configured to set a control waiting time, depending on the signal present duration detected by the period detecting circuit; and
a control circuit configured to limit outputting of the amplification circuit after the control waiting time set by the time setting circuit has elapsed since the signal detecting circuit detected the signal absent state of the input signal.

2. The audio output device of claim 1, wherein
the time setting circuit sets the control waiting time to a first period of time when the signal present duration is shorter than a predetermined period of time, and to a second period of time longer than the first period of time when the signal present duration is longer than the predetermined period of time.

3. The audio output device of claim 1, wherein
the control circuit limits the outputting of the amplification circuit by stopping the amplification circuit.

4. The audio output device of claim 1, wherein
the period detecting circuit measures the signal present duration by counting, and
the time setting circuit sets the control waiting time, depending on a count value of the period detecting circuit.

5. The audio output device of claim 1, further comprising:
a loudspeaker,
wherein the amplification circuit includes:
a first amplifier configured to amplify the input signal; and
a second amplifier configured to invert and amplify the input signal, and the loudspeaker is driven by outputs of the first and second amplifiers.

6. The audio output device of claim 1, wherein
the amplification circuit, the signal detecting circuit, the period detecting circuit, the time setting circuit, and the control circuit are integrated in the same semiconductor integrated circuit.
